(19) United States
(12) Patent Application Publication
(10) Pub. No.: US 2005/0090113 A1
(43) Pub. Date: Apr. 28, 2005

(54) Method for removing photoresist after etching the metal layer

(76) Inventor: Shuang Hsun Chang, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 10/968,098

(22) Filed: Oct. 20, 2004

(30) Foreign Application Priority Data
Oct. 24, 2003 (CN) 200310108120.5

(51) Int. Cl. H01L 21/4763; H01L 21/302; H01L 21/461

(52) U.S. Cl. 438/704

(57) ABSTRACT

A method for removing photoresist after etching a metal layer is provided. A plasma etching process is added to a dry and wet strip process to remove sediment and metal residue on the sidewalls of the metal layer quickly, thereby reducing the required time of the next wet strip process and the preventing miro-masking phenomenon. Also, it can be applied in nano-processes so as to gain more margins in regards to small metal bridges.

### BACKGROUND OF THE INVENTION

1. Field of the Invention

The present invention relates to a method for removing photoresist, in particular, to a method for removing photoresist after etching the metal layer.

2. Description of the Prior Art

During manufacture of integrated circuits, commonly referred to as semiconductor chips or microchips, several iterations of a photolithographic process are used. In this manufacturing process, dielectric, barrier or electrically conducting layers such as silicon dioxide, silicon nitride or metal are first deposited upon a substrate such as a silicon or gallium arsenide wafer by any of several suitable processes such as thermal oxidation, chemical vapor deposition, sputtering, ion implantation or vacuum evaporation.

Since aluminum has low resistance, and is easy to deposit and etch, aluminum is widely applied in the semiconductor process. In advanced ICs, the density of the device is limited to the area of the interconnects, and the metal layer is anisotropic etched so as to shrink the distance between the interconnects, thereby increasing the wiring ability of interconnects. The anisotropic etch of aluminum is a very important process in IC processing.

As the feature sizes shrink, the aspect ratio of the etched pattern is increased. The reactant in the etch process can not be eliminated so as to form a metal residue. Also, the thickness of photoresist is relatively increased, resulting in increased etching difficulty, for example, 0.25 μm of aluminum line, and a thickness of 0.5 μm. The original thickness of the photoresist is 0.5˜1 μm. The entire aspect ratio is about 4˜6. In order to increase the ability of anisotropic etching, some gases, such as SiCl₄, CCl₄, CHF₃, and CHCl₃ need to be added. Chlorine or fluorine atoms in some gases react with carbon or silicon atoms in the photoresist to form sediment deposited on the metal sidewalls preventing ion bombardment.

This sediment and metal residue easily causes chip contamination. If this sediment and metal residue can not be removed cleanly, the wafer is easily subjected to the contamination, resulting in the so-called Micromasking phenomenon. In order to prevent this phenomenon, the time of the wet strip process is extended in conventional processing so as to obtain a better clean level. However, the metal layer easily causes the defect in the conventional process.

Therefore, there is need for a method for effectively removing photoresist after etching the metal layer that prevents the aforementioned problems and obtains a better clean level, which is able to be used in a metal bridge structure with smaller size so as to obtain a larger boundary.

### SUMMARY OF THE INVENTION

The present invention provides a method for removing photoresist after etching the metal layer, which can be applied in a metal bridge structure with smaller size so as to obtain a larger boundary.

The present invention also provide a method for removing photoresist after etching the metal layer, which reduces the sheet-shaped polymer strip resulting in wafer and chamber contamination.

The present invention reduces the mircomasking phenomenon.

According to the present invention, a method for removing photoresist after etching the metal layer is provided, comprising the steps of: providing a semiconductor substrate having a MOS device thereon, wherein a metal layer and a patterned photoresist layer are formed on the semiconductor substrate in sequence; etching the metal layer using the patterned photoresist layer as a mask; performing three photoresist removing processes on the semiconductor substrate: performing a dry strip process on the patterned photoresist layer; performing a dry etching on the semiconductor substrate by using a plasma containing BCl3, O2, and Cl2; and performing a wet strip process on the semiconductor substrate to complete the photoresist removing process.

These and other objectives of the present invention will become obvious to those of ordinary skill in the art after reading the following detailed description of the preferred embodiment.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1 through 5 are sectional diagrams illustrating the structure of each step according to a preferred embodiment of the present invention.

### DETAILED DESCRIPTION OF THE PREFERRED EMBODIMENTS

The present invention can be widely applied in the photoresist removing process after etching the various materials of metal layers in the semiconductor process. A method for removing photoresist after etching the metal layer will be described in detail below by way of one preferred embodiment. It should be noted, however, that the present invention is not limited to this embodiment, and the material of metal layer and the sediments produced from the reaction can be replaced that are apparent for those skilled in the art are within the scope of the present invention.

The present invention provides a method for removing photoresist after etching the metal layer, which adds a dry etching step into the dry and wet strip step to remove the organic and inorganic sediment and the metal residue attached to the sidewalls of metal layer, thereby reducing the required time for the wet strip process.

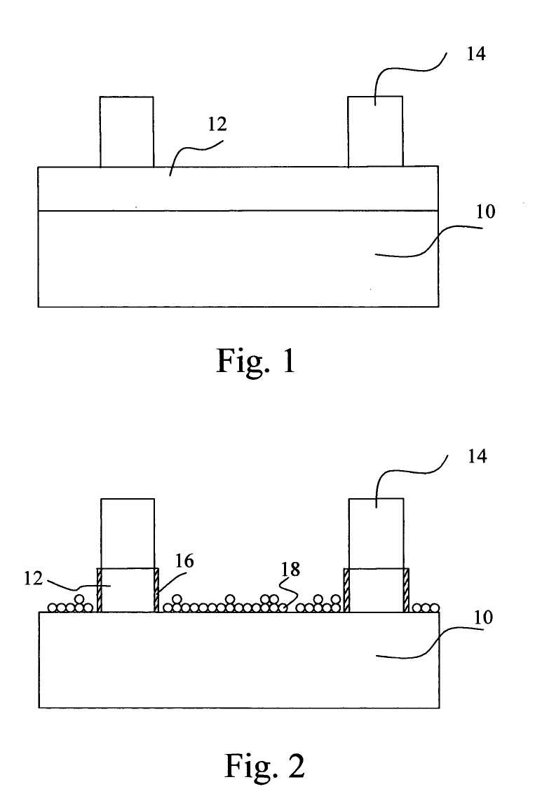

FIGS. 1 through 5 are sectional diagrams illustrating the structure of each step according to the preferred embodiment of the present invention.

Referring FIG. 1, a semiconductor substrate 10 has MOS and some base devices formed thereon. A metal layer 12 composed of aluminum is deposited on the semiconductor substrate 10. A patterned photoresist layer 14 is formed on the metal layer 12. Next, the metal layer 12 is etched using the patterned photoresist layer 14 as a mask. During the etching process, since the metal layer 12 reacts with the atmosphere, sediment 16 containing chloride or residual gas remains on the sidewalls of the metal layer 12. The aspect ratio is increased due to the high etched pattern so that the defect metal residue 18 is easily produced, forming the structure shown in FIG. 2.

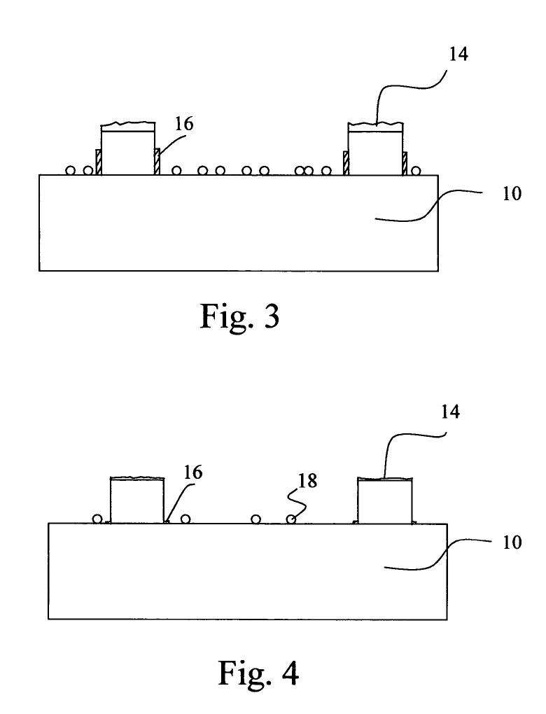

Next, an advanced strip and passivation dry strip (ASP dry strip) is performed to remove the organic component in the patterned photoresist layer 14, forming the structure shown in FIG. 3. The ASP dry strip uses oxygen as the plasma.

The dry etching process is performed using the mixed gases of BCl₃, O₂, and Cl₂, forming the structure shown in FIG. 4. The oxygen particle can eliminate sediment 16 like hydrocarbon, and remove the organic component in the residual patterned photoresist layer 14. BCl₃ and Cl₂ can easily remove the inorganic component in the sediment 16, such as aluminum, titanium and the like and the metal residue 18. The reaction formula is as follows;
BCl₃→BCl₂+Cl
Cl₂→2Cl
Al+¾Cl₂→AlCl₃↑
AlxCyHz+O₂=CO↑+H₂O↑+Al₂O₃

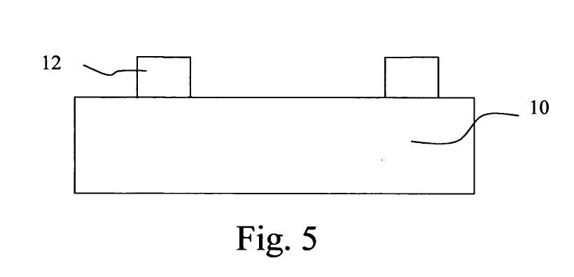

Finally, an isotropy wet strip process is performed to remove the residual patterned photoresist layer 14 and the sediment 16 and the metal residue 18 which were unable to be removed in the aforesaid etch removing process, forming a completed patterned metal layer of a semiconductor substrate structure as shown in FIG. 5.

Therefore, the present invention can reduce the cavity formation caused by the corrosion from the solvent of a wet removing photoresist process and the metal layer, and can prevent wafer and chamber contamination by the sheet-shaped polymer strip in the conventional process, so as to gain more margins in regards to small metal bridge issues.

According to the present invention, an etching recipe containing BCl₃, O₂, and Cl₂ is added after the conventional dry strip process in order to perform a dry etching on the semiconductor substrate, thereby obtaining a better removal efficacy by using the shorter time process of wet strip. Also, the sediment produced by anisotropic etching and the metal residue due to the high aspect ratio are effectively removed in order to reduce the micro-masking phenomenon.

The embodiment above is only intended to illustrate the present invention; it does not, however, limit the present invention to the specific embodiment. Accordingly, various modifications and changes may be made without departing from the spirit and scope of the present invention as described in the following claims.

1. A method for removing photoresist after etching a metal layer, comprising:
providing a semiconductor substrate having a MOS device, having a metal layer and a patterned photoresist layer in sequence formed thereon;
etching the metal layer using the patterned photoresist layer as a mask; and
performing three steps of photoresist removal processing on the semiconductor substrate comprising:
performing a dry strip process on the patterned photoresist layer;
performing a dry etching process on the semiconductor substrate by using a plasma containing BCl₃, O₂, and Cl₂; and
performing a wet strip process on the semiconductor substrate.

2. The method for removing photoresist after etching a metal layer of claim 1, wherein the dry strip process uses oxygen as a plasma.

3. The method for removing photoresist after etching a metal layer of claim 1, wherein the metal layer comprises aluminum.

4. The method for removing photoresist after etching a metal layer of claim 1, wherein the wet strip process uses a solvent to remove inorganic compound in the process.

5. The method for removing photoresist after etching a metal layer of claim 1, wherein etching the metal layer comprises reaction ion etching.

6. The method for removing photoresist after etching a metal layer of claim 1, wherein after the step of etching the metal layer, sediment is formed on the sidewalls of the metal layer, and the sediment is eliminated by the three steps of photoresist removal processing.

7. The method for removing photoresist after etching a metal layer of claim 6, wherein the sediment contains chloride and residual gas.

8. The method for removing photoresist after etching a metal layer of claim 6, wherein O₂ in the plasma removes hydrocarbon in the sediment and the residual photoresist layer.

9. The method for removing photoresist after etching a metal layer of claim 6, wherein BCl₃ and Cl₂ in the plasma reacts with the inorganic compound in the sediment to eliminate metal residue.
